(19) United States
(12) Patent Application Publication
(10) Pub. No.: US 2025/0239430 A1
(43) Pub. Date: Jul. 24, 2025

(54) CHARGED PARTICLE BEAM DEVICE

(71) Applicant: Hitachi High-Tech Corporation, Tokyo (JP)

(72) Inventors: Takafumi MIWA, Tokyo (JP); Momoyo ENYAMA, Tokyo (JP); Keiichiro HITOMI, Tokyo (JP); Go MIYA, Tokyo (JP); Yuzuru MIZUHARA, Tokyo (JP)

(21) Appl. No.: 19/018,372

(22) Filed: Jan. 13, 2025

(30) Foreign Application Priority Data
Jan. 18, 2024 (JP) 2024-005755

(51) Int. Cl. H01J 37/244; H01J 37/20; H01J 37/22; H01J 37/28

(52) U.S. Cl. CPC H01J 37/244; H01J 37/20; H01J 37/224; H01J 37/28; H01J 2237/004

(57) ABSTRACT

Provided is a charged particle beam device capable of correcting an aberration that occurs when an outer peripheral portion of a sample is observed.

The charged particle beam device includes: a sample stage configured to hold a sample; a charged particle beam source configured to emit a charged particle beam to be emitted onto the sample; a lens configured to focus the charged particle beam on the sample; an aberration corrector configured to correct an aberration of the charged particle beam; a deflector configured to perform scanning with the charged particle beam; a detector configured to detect a charged particle emitted from the sample by being scanned with the charged particle beam; and a control unit configured to generate an observation image of the sample based on a detection signal output from the detector and control an operation of each of the parts. The control unit controls the aberration corrector by collating a position of the sample stage when an outer peripheral portion of the sample is observed with a correction table indicating a relation between the position of the sample stage and a control amount of the aberration corrector.

### CLAIM OF PRIORITY

The present application claims priority from Japanese Patent Application JP 2024-005755 filed on Jan. 18, 2024, the content of which is hereby incorporated by reference into this application.

### TECHNICAL FIELD

The present invention relates to a charged particle beam device, and particularly relates to measurement and inspection of an outer peripheral portion of a sample.

### BACKGROUND ART

A charged particle beam device such as an electron microscope or an ion microscope is used for observation of various samples having a fine structure, and particularly in a manufacturing process of a semiconductor device, the charged particle beam device is used for dimension measurement, defect inspection, and the like of a pattern formed on a semiconductor wafer. In order to improve a yield of a semiconductor device, it is necessary to measure and inspect not only a central portion but also an outer peripheral portion of a semiconductor wafer, whereas in the outer peripheral portion, an electric field may be disturbed, and a desired position may not be irradiated with an electron beam.

PTL 1 discloses a semiconductor inspection device that corrects a disturbance of an electric field in an outer peripheral portion of a sample. Specifically, the disturbance of the electric field in the outer peripheral portion of the sample is corrected by applying a voltage to a correction electrode provided outside a lower portion of the sample to generate a correction electric field. The voltage to be applied to the correction electrode is controlled according to a distance between a position irradiated with an electron beam and the outer peripheral portion of the sample, a tapered shape of the outer peripheral portion of the sample, and a thickness of the sample, and the distance between the electron beam irradiation position and the outer peripheral portion of the sample is obtained based on the electron beam irradiation position and a diameter and a central position of the sample.

### CITATION LIST

### Patent Literature

PTL 1: JP2014-216183A

### SUMMARY OF INVENTION

### Technical Problem

However, in PTL 1, no consideration is given to an aberration that occurs when the outer peripheral portion of the sample is observed. In the outer peripheral portion of the sample, an observation image is distorted due to the aberration that occurs due to an asymmetry of a structure, which interferes with the observation of the sample.

Therefore, an object of the invention is to provide a charged particle beam device capable of correcting an aberration that occurs when an outer peripheral portion of a sample is observed.

### Solution to Problem

In order to achieve the above object, the invention provides a charged particle beam device, including: a sample stage configured to hold a sample; a charged particle beam source configured to emit a charged particle beam to be emitted onto the sample; a lens configured to focus the charged particle beam on the sample; an aberration corrector configured to correct an aberration of the charged particle beam; a deflector configured to perform scanning with the charged particle beam; a detector configured to detect a charged particle emitted from the sample by being scanned with the charged particle beam; and a control unit configured to generate an observation image of the sample based on a detection signal output from the detector and control an operation of each of the parts, in which the control unit controls the aberration corrector by collating a position of the sample stage when an outer peripheral portion of the sample is observed with a correction table indicating a relation between the position of the sample stage and a control amount of the aberration corrector.

### Advantageous Effects of Invention

According to the invention, it is possible to provide a charged particle beam device capable of correcting an aberration that occurs when an outer peripheral portion of a sample is observed.

### BRIEF DESCRIPTION OF DRAWINGS

FIG. 1 is a diagram illustrating an overall configuration of a scanning electron microscope which is an example of a charged particle beam device according to a first embodiment.

FIG. 2A is a diagram illustrating a wien filter which is an example of an aberration corrector.

FIG. 2B is a diagram illustrating a hexapole which is an example of the aberration corrector.

FIG. 3 is a diagram illustrating an example of a processing flow for creating a correction table according to the first embodiment.

FIG. 4 is a diagram illustrating positions of a sample stage which are measurement positions.

FIG. 5A is a diagram illustrating an example of an observation image before a control amount of the aberration corrector is changed.

FIG. 5B is a diagram illustrating an example of an observation image after the control amount of the aberration corrector is changed.

FIG. 6A is a diagram illustrating an example of the correction table according to the first embodiment.

FIG. 6B is a diagram illustrating an example of the correction table according to the first embodiment.

FIG. 7 is a diagram illustrating an example of a processing flow of aberration correction according to the first embodiment.

FIG. 8 is a diagram illustrating an example of a display screen according to the first embodiment.

FIG. 9 is a diagram illustrating an overall configuration of a scanning electron microscope which is an example of the charged particle beam device according to the first embodiment.

FIG. 10 is a diagram illustrating an example of a processing flow for creating a correction table according to a second embodiment.

FIG. 11 is a diagram illustrating a shape of an outer peripheral portion of a sample.

FIG. 12 is a diagram illustrating a height sensor.

FIG. 13A is a diagram illustrating an example of the correction table according to the second embodiment.

FIG. 13B is a diagram illustrating an example of the correction table according to the second embodiment.

FIG. 14 is a diagram illustrating an example of a processing flow of aberration correction according to the second embodiment.

FIG. 15 is a diagram illustrating an overall configuration of a scanning electron microscope which is an example of a charged particle beam device according to a third embodiment.

FIG. 16 is a diagram illustrating an example of a processing flow for creating a correction table according to the third embodiment.

FIG. 17 is a diagram illustrating an example of the correction table according to the third embodiment.

FIG. 18 is a diagram illustrating an example of a processing flow of aberration correction according to the third embodiment.

### DESCRIPTION OF EMBODIMENTS

Hereinafter, embodiments of a charged particle beam device according to the invention will be described with reference to the accompanying drawings. The charged particle beam device is a device for observing or processing a sample by irradiating the sample with a charged particle beam, and includes a scanning electron microscope, a scanning ion microscope, a scanning transmission electron microscope, and the like. Hereinafter, a scanning electron microscope that observes a sample by using an electron beam, which is one type of a charged particle beam, will be described as an example of the charged particle beam device.

### First Embodiment

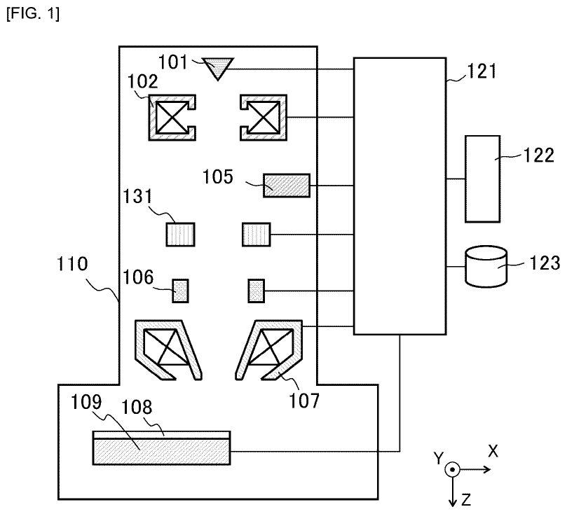

An overall configuration of a scanning electron microscope according to a first embodiment will be described with reference to FIG. 1. An electron gun 101, a condenser lens 102, a detector 105, an aberration corrector 131, a deflector 106, an objective lens 107, and a sample stage 109 are provided in a housing 110 of the scanning electron microscope, and operations of these parts are controlled by a control unit 121. The control unit 121 is connected to an input and output unit 122 used for inputting and outputting various data related to an observation image, and a storage unit 123 that stores various data. Further, the inside of the housing 110 is evacuated by a vacuum pump or the like, and a sample 108 is held on the sample stage 109. The sample 108 includes a calibration sample and an observation sample. Hereinafter, each of the parts will be described. In FIG. 1, a vertical direction is a Z direction, and horizontal directions are an X direction and a Y direction.

The electron gun 101 emits an electron beam to be emitted onto the sample 108. The condenser lens 102 focuses the electron beam emitted from the electron gun 101. The deflector 106 deflects the electron beam in a manner of scanning an observation region of the sample 108. The objective lens 107 focuses the deflected electron beam on the observation region of the sample 108. The sample stage 109 is, for example, an electrostatic chuck that holds the sample 108, and moves within an XY plane to set the observation region of the sample 108 at a desired position. A position of the sample stage 109 is transmitted to the control unit 121. The detector 105 detects charged particles such as secondary electrons or backscattered electrons emitted from the sample 108 when irradiated with the electron beam, and transmits a detection signal to the control unit 121.

The control unit 121 is, for example, a computing unit, and generates an observation image of the sample 108 based on the detection signal transmitted from the detector 105. The generated observation image is displayed on a display unit included in the input and output unit 122 or stored in the storage unit 123, and is used for dimension measurement, defect inspection, and the like of the sample 108.

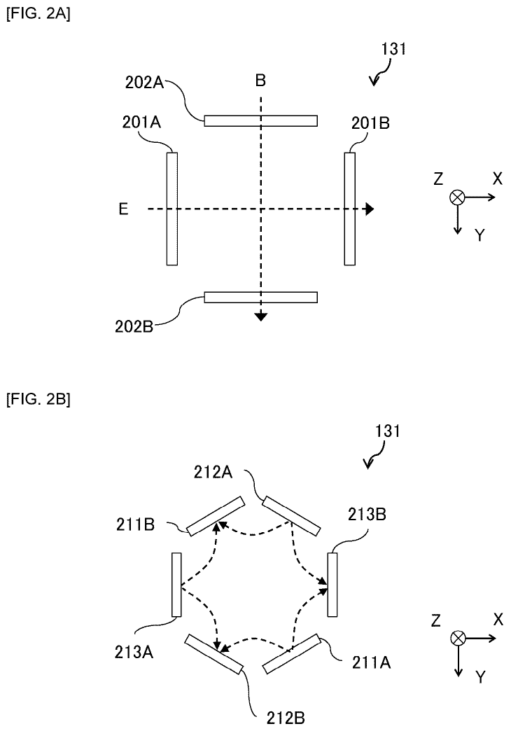

The aberration corrector 131 is arranged between the condenser lens 102 and the deflector 106, and corrects an aberration of the electron beam in a manner that the aberration becomes less than a predetermined value. The aberration corrected by the aberration corrector 131 includes, for example, a chromatic aberration, a coma aberration, and an astigmatism. An example of the aberration corrector 131 will be described with reference to FIGS. 2A and 2B.

FIG. 2A illustrates a wien filter that corrects a chromatic aberration. The wien filter is implemented in a manner that an electric field E formed by an electrode 201A and an electrode 201B is orthogonal to a magnetic field B formed by a magnetic pole 202A and a magnetic pole 202B. An intensity of the electric field E is controlled by adjusting a voltage to be applied to the electrode 201A and the electrode 201B. The magnetic pole 202A and the magnetic pole 202B are each implemented by a coil or a combination of a coil and a magnetic body, and an intensity of the magnetic field B is controlled by adjusting an excitation current to be supplied to the coil. As illustrated in FIG. 2A, the electric field E and the magnetic field B that are orthogonal to each other exert an opposite force on the electron beam emitted from the electron gun 101 onto the sample 108, and thus by controlling the intensities of the electric field E and the magnetic field B according to the energy of the electron beam, the chromatic aberration can be corrected to be less than a predetermined value. The correction of the chromatic aberration executed by the wien filter illustrated in FIG. 2A is limited to the X direction, and in order to enable an correction of the chromatic aberration in any direction, the wien filter illustrated in FIG. 2A may be combined with a wien filter that corrects a chromatic aberration in the Y direction.

When the wien filter illustrated in FIG. 2A is provided closer to the sample stage 109 than the detector 105, the secondary electrons or backscattered electrons emitted from the sample 108 can reach the detector 105 more easily. The wien filter does not exert a deflection action on the electron beam emitted from the electron gun 101 onto the sample 108, but has a deflection action on the secondary electrons or backscattered electrons moving from the sample 108 toward the detector 105. Therefore, in addition to controlling the wien filter to correct the chromatic aberration, the wien filter can be controlled in a manner that the secondary electrons or backscattered electrons are more easily drawn into the detector 105. Meanwhile, in order to correct the chromatic aberration while avoiding an influence on the secondary electrons or backscattered electrons as described above, the wien filter illustrated in FIG. 2A may be provided at a position farther away from the sample stage 109 than the detector 105.

FIG. 2B illustrates a hexapole that corrects the coma aberration. The hexapole includes a magnetic pole 211A and a magnetic pole 211B, a magnetic pole 212A and a magnetic pole 212B, and a magnetic pole 213A and a magnetic pole 213B, which are arranged at equal distances from a central position. Each magnetic pole is arranged at an angle shifted by 60° from the central position, and is implemented by a coil or a combination of a coil and a magnetic body. The adjacent magnetic poles have different polarities, and a magnetic field from the magnetic pole 211A toward the magnetic poles 212B and 213B, a magnetic field from the magnetic pole 212A toward the magnetic poles 213B and 211B, and a magnetic field from the magnetic pole 213A toward the magnetic poles 211B and 212B are formed. The formed magnetic field is controlled by adjusting an excitation current to be supplied to the coil. The coma aberration is corrected to be less than a predetermined value by controlling the magnetic field.

The aberration corrector that corrects the coma aberration may be a multipole having six or more poles, or may be implemented by a plurality of electrodes that form an electric field instead of a plurality of magnetic poles that form a magnetic field. When the aberration corrector that corrects the coma aberration is implemented by a plurality of electrodes, an electric field controlled by adjusting a voltage to be applied to the electrodes corrects the coma aberration to be less than the predetermined value. The aberration corrector 131 is not limited to those illustrated in FIGS. 2A and 2B. For example, the aberration corrector 131 may be a multipole lens implemented by a plurality of electrodes or magnetic poles that form a multipole field for correcting a plurality of aberrations. Further, these aberration correctors may be implemented in multiple stages.

However, when an outer peripheral portion of the sample 108 is observed, the observation image is distorted due to an aberration that occurs due to an asymmetry of a structure, which interferes with the observation of the sample 108. The amount of aberration that occurs varies depending on a distance from an outer edge of the sample 108 to the observation region, that is, depending on the position of the sample stage 109 when the outer peripheral portion of the sample 108 is observed.

Therefore, in the first embodiment, the aberration corrector 131 is operated based on the position of the sample stage 109 when the outer peripheral portion of the sample 108 is observed, thereby correcting the aberration that occurs when the outer peripheral portion of the sample 108 is observed and acquiring an observation image in which the distortion is prevented. In order to operate the aberration corrector 131 based on the position of the sample stage 109 when the outer peripheral portion of the sample 108 is observed, a correction table indicating a relation between the position of the sample stage 109 and a control amount of the aberration corrector 131 is created in advance.

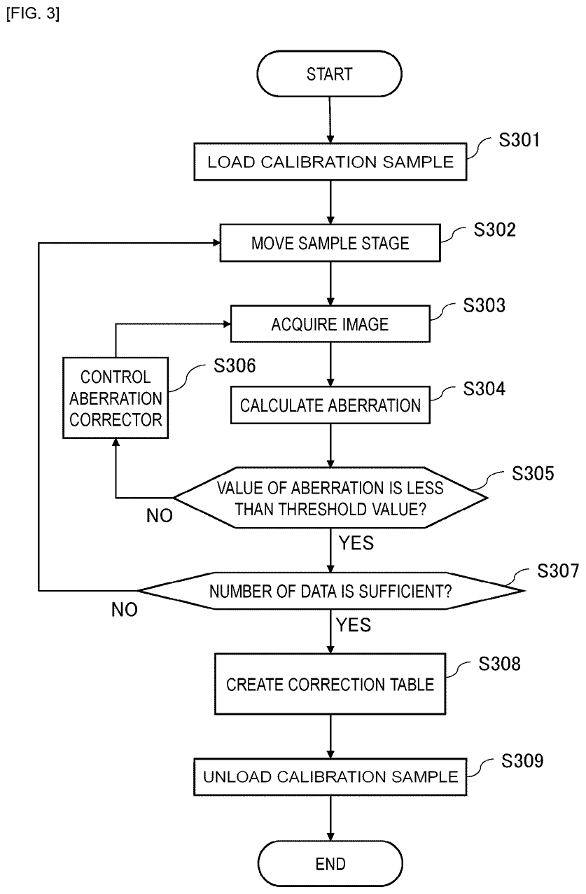

An example of a processing flow for creating the correction table will be described for each processing step with reference to FIG. 3.

### (S301)

A calibration sample is loaded into the scanning electron microscope. The calibration sample is a sample used for creating the correction table, is a sample having a known shape and size, for example, a silicon wafer having a circular shape, and is provided at the center of the sample stage 109.

### (S302)

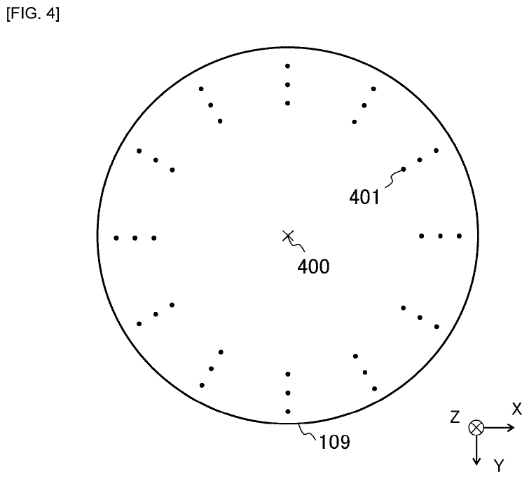

The control unit 121 moves the sample stage 109 in a manner that an observation region of an outer peripheral portion of the calibration sample is provided at a position irradiated with the electron beam. Specifically, the sample stage 109 is moved in a manner that any one of a plurality of measurement positions 401 illustrated in FIG. 4 is irradiated with the electron beam. The measurement positions 401 illustrated in FIG. 4 include 36 points provided rotationally symmetrically on concentric circles sharing a center point 400 of the circular sample stage 109. The measurement positions 401 are not limited to those illustrated in FIG. 4.

### (S303)

The control unit 121 operates each of the parts in the housing 110 to acquire an observation image of the outer peripheral portion of the calibration sample.

### (S304)

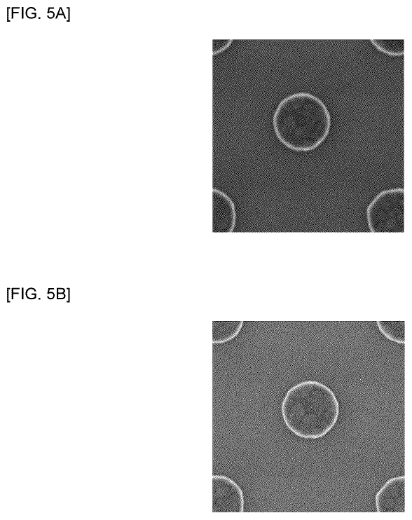

The control unit 121 calculates an aberration based on the observation image acquired in S303. The aberration is calculated based on, for example, blur included in the observation image. When there are observation images acquired before and after controlling the aberration corrector 131, or when there are observation images acquired before and after changing a control value of each part in the scanning electron microscope in a manner of changing the energy of the electron beam, the aberration may be calculated based on a value based on a difference between the two observation images, for example, may be calculated based on a shift amount obtained from the two observation images. FIG. 5A illustrates an example of the observation image before controlling the aberration corrector 131, and FIG. 5B illustrates an example of the observation image after controlling the aberration corrector 131. The shift amount is obtained from such two observation images, and a chromatic aberration that occurs as an influence of a shift of a position where the electron beam is focused is calculated from the shift amount.

### (S305)

The control unit 121 determines whether the value of the aberration calculated in S304 is less than a threshold value determined in advance. If the value of the aberration is less than the threshold value, the processing proceeds to S307, and if the value of the aberration is equal to or larger than the threshold value, the processing returns to S303 via S306. That is, the processing of S303 to S306 is repeated until the value of the aberration becomes less than the threshold value. The threshold value is determined in advance based on a correction accuracy of the aberration.

### (S306)

The control unit 121 controls the aberration corrector 131. When the processing of S303 to S306 is repeated a plurality of times, the control amount of the aberration corrector 131 may be set based on a change in the value of the aberration calculated in S304. For example, when the value of the aberration increases by increasing the control amount of the aberration corrector 131, the control amount is decreased.

### (S307)

The control unit 121 determines whether the number of data is sufficient. If the number of data is sufficient, the processing proceeds to S308, and if insufficient, the processing returns to S302. That is, the processing of S302 to S307 is repeated until the control amount with which the value of the aberration becomes less than the threshold value is obtained for all the measurement positions 401 as illustrated in FIG. 4.

### (S308)

The control unit 121 creates a correction table by using the control amount of the aberration corrector 131 with which the aberration becomes less than the threshold value at each measurement position 401. The created correction table is stored in the storage unit 123.

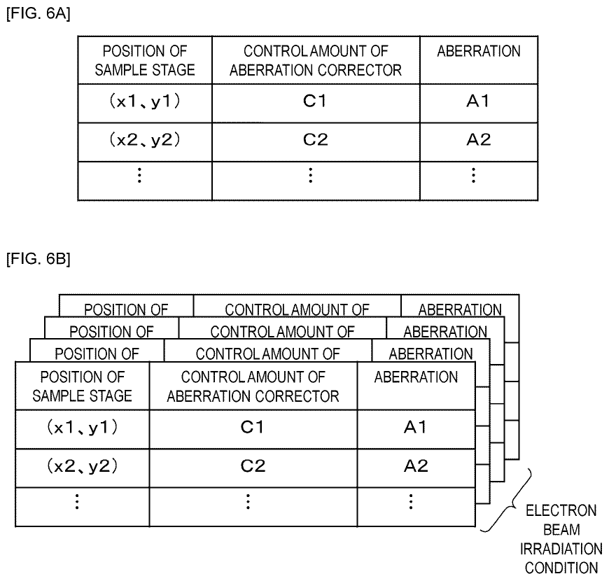

FIGS. 6A and 6B illustrate examples of the correction table. The correction table illustrated in FIG. 6A includes the position of the sample stage 109, the control amount of the aberration corrector 131, and the aberration. The aberration is not necessary, and the control amount of the aberration corrector 131 with which the aberration becomes less than the threshold value at each position of the sample stage 109 may be stored in the correction table. Even when the position of the sample stage 109 is the same, the value of the aberration also changes if an electron beam irradiation condition such as an acceleration voltage of the electron beam is different, and therefore, as illustrated in FIG. 6B, a correction table for each electron beam irradiation condition may be created.

### (S309)

The calibration sample is unloaded from the scanning electron microscope.

According to the processing flow described with reference to FIG. 3, a correction table indicating a relation between the position of the sample stage 109 and the control amount of the aberration corrector 131 is created. The created correction table is used for aberration correction.

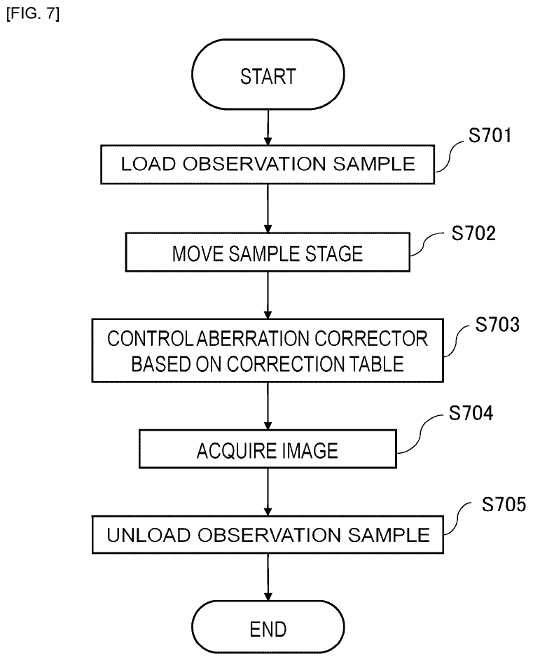

An example of a processing flow of the aberration correction will be described for each processing step with reference to FIG. 7.

### (S701)

An observation sample is loaded into the scanning electron microscope. The observation sample is a sample to be subjected to dimension measurement, defect inspection, and the like.

### (S702)

The control unit 121 moves the sample stage 109 in a manner that an observation region of an outer peripheral portion of the observation sample is provided at the position irradiated with the electron beam, and acquires a position of the sample stage 109 after the movement.

### (S703)

The control unit 121 controls the aberration corrector 131 by collating the position of the sample stage 109 acquired in S702 with the correction table. That is, a control amount read out by collating the position of the sample stage 109 when the outer peripheral portion of the observation sample is observed with the correction table is set for the aberration corrector 131. The aberration corrector 131 in which the control amount read out from the correction table is set corrects the aberration in a manner that the aberration becomes less than the threshold value.

When the position of the sample stage 109 acquired in S702 is not stored in the correction table, the control amount at the position may be calculated by interpolation processing. That is, control amounts corresponding to four positions close to the position of the sample stage 109 acquired in S702 may be read out from the correction table, and the control amount at the position may be calculated by the interpolation processing using the read four control amounts.

When the correction table for each electron beam irradiation condition as illustrated in FIG. 6B is created, the correction table is selected according to the electron beam irradiation condition set when the observation sample is observed, and the aberration corrector 131 is controlled based on the selected correction table.

### (S704)

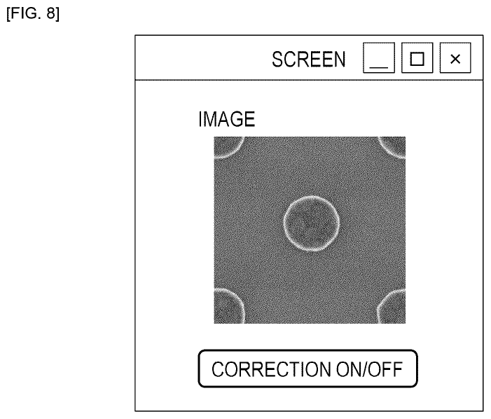

The control unit 121 operates each of the parts in the housing 110 to acquire an observation image of the observation sample. Since the aberration corrector 131 is controlled in a manner that the aberration becomes less than the threshold value in S703, an observation image in which distortion due to the aberration is prevented can be acquired in S704. The acquired observation image is displayed on, for example, a display screen illustrated in FIG. 8. The screen illustrated in FIG. 8 includes a “correction ON/OFF” button, and ON and OFF of the aberration correction are switched when the button is pressed. Instead of pressing the “correction ON/OFF” button, the control unit 121 may control parameters for switching ON and OFF of the aberration correction.

### (S705)

The observation sample is unloaded from the scanning electron microscope.

According to the processing flow described with reference to FIG. 7, the aberration corrector 131 is operated based on the position of the sample stage 109 when the outer peripheral portion of the observation sample is observed, and the observation image in which distortion due to the aberration is prevented can be acquired. The observation image thus acquired can be used for dimension measurement, defect inspection, and the like of the outer peripheral portion of the observation sample.

### Second Embodiment

In the first embodiment, the aberration correction is performed by operating the aberration corrector 131 based on the position of the sample stage 109 when the outer peripheral portion of the observation sample is observed. The aberration that occurs when the outer peripheral portion of the sample of the observation sample is observed changes according to a cross-sectional shape of an outer edge of the observation sample or a positional deviation of the observation sample with respect to the sample stage 109. In a second embodiment, the aberration corrector 131 is operated based on the position of the sample stage 109 and the shape and positional deviation of the observation sample. The same reference numerals are given to the same configurations and processing as those of the first embodiment, and the description thereof will be omitted or simplified.

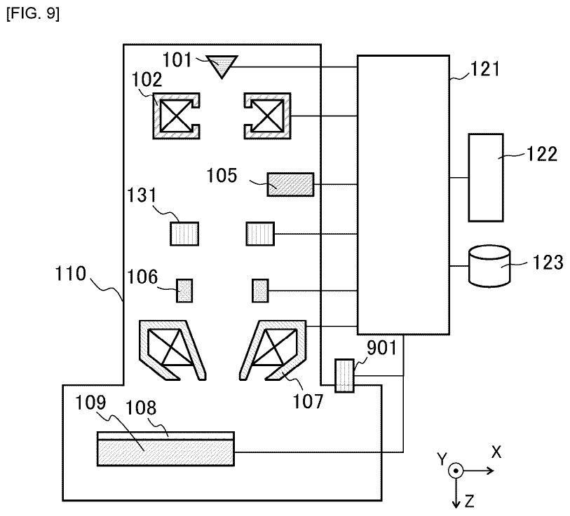

An overall configuration of a scanning electron microscope according to the second embodiment will be described with reference to FIG. 9. In the scanning electron microscope according to the second embodiment, a measuring instrument 901 is added to the configuration according to the first embodiment. The measuring instrument 901 optically measures the shape and positional deviation of the sample 108, and is, for example, an optical sensor or an optical microscope, and performs measurements by bright-field observation, dark-field observation, and confocal observation. When the measuring instrument 901 measures the shape and positional deviation of the sample 108, the sample stage 109 is moved to a position immediately below the measuring instrument 901.

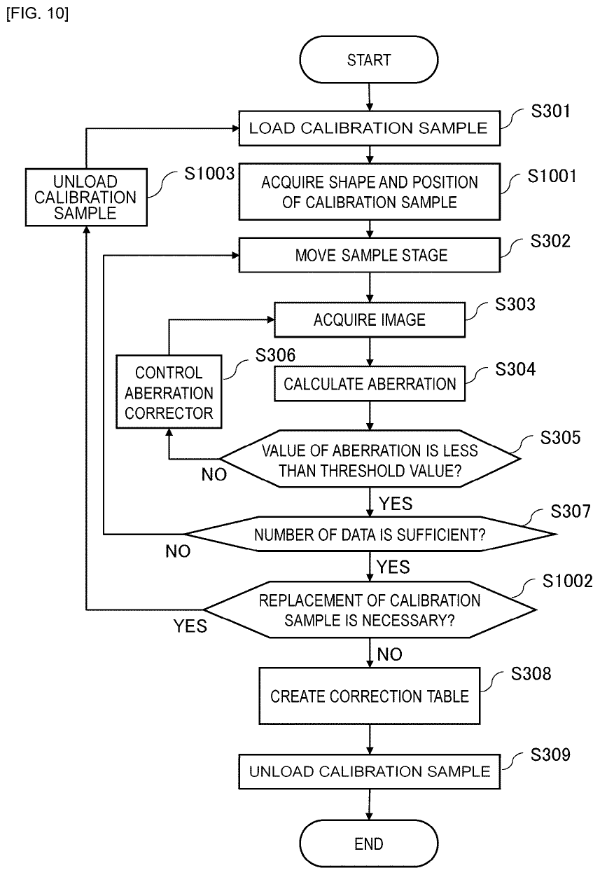

An example of a processing flow for creating a correction table according to the second embodiment will be described for each processing step with reference to FIG. 10. In the second embodiment, S1001, S1002, and S1003 are added to the processing flow illustrated in FIG. 3, and thus the descriptions of the processing steps other than S1001, S1002, and S1003 will be simplified.

### (S301)

As in the first embodiment, a calibration sample is loaded into the scanning electron microscope.

### (S1001)

The control unit 121 acquires the shape and position of the calibration sample loaded in S301. The shape and position of the calibration sample are acquired by being measured by the measuring instrument 901, or by reading out values measured in advance outside the scanning electron microscope.

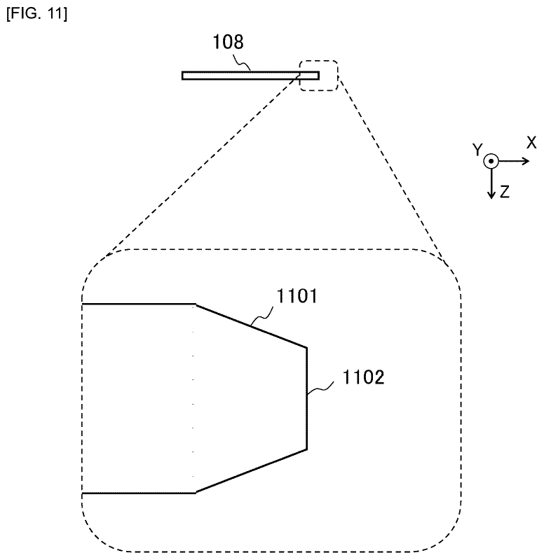

A cross-sectional shape of an outer edge of the sample 108 will be described with reference to FIG. 11. The sample 108 has bevels 1101 and an apex 1102 on the outer edge. The bevel 1101 is a sloped surface, and the apex 1102 is a vertex of the outer edge. An inclination angle of the bevel 1101 with respect to a horizontal plane and a distance from a center point of the sample 108 to the apex 1102 are defined by specifications, whereas there are variations for each sample 108. Therefore, in S1001, measurement values related to the bevel 1101 and the apex 1102 are acquired for each calibration sample.

Coordinates of the apex 1102 on an XY plane are measured at least at three positions, and coordinates of the center point of the calibration sample are calculated based on the measured coordinates. The positional deviation of the calibration sample with respect to the sample stage 109 is obtained based on the coordinates of the center point of the calibration sample and coordinates of a center point of the sample stage 109.

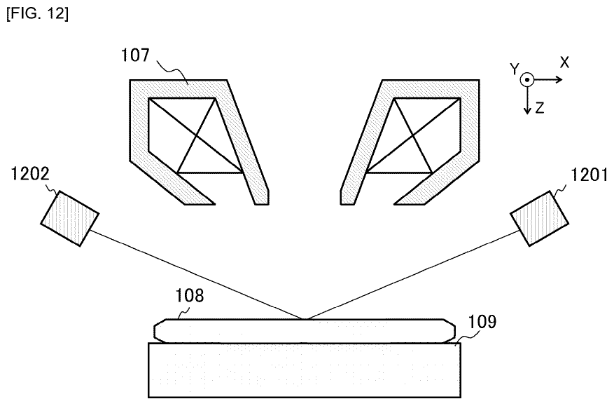

The measurement of the shape and position of the calibration sample is not limited to using the measuring instrument 901, and a height sensor illustrated in FIG. 12 may be used. The height sensor illustrated in FIG. 12 includes a light emitting unit 1201 and a light receiving unit 1202, and measures a height of the sample 108 by the light receiving unit 1202 detecting light emitted from the light emitting unit 1201 and reflected by an upper surface of the sample 108. Since the height sensor can perform measurement in a shorter time than the measuring instrument 901, throughput can be improved.

### (S302)

As in the first embodiment, the control unit 121 moves the sample stage 109 in a manner that an observation region of an outer peripheral portion of the calibration sample is provided at a position irradiated with an electron beam.

### (S303)

As in the first embodiment, the control unit 121 operates each of the parts in the housing 110 to acquire an observation image of the outer peripheral portion of the calibration sample.

### (S304)

As in the first embodiment, the control unit 121 calculates an aberration based on the observation image acquired in S303.

### (S305)

As in the first embodiment, the control unit 121 determines whether the value of the aberration calculated in S304 is less than a threshold value determined in advance. If the value of the aberration is less than the threshold value, the processing proceeds to S307, and if the value of the aberration is equal to or larger than the threshold value, the processing returns to S303 via S306.

### (S306)

As in the first embodiment, the control unit 121 controls the aberration corrector 131.

### (S307)

As in the first embodiment, the control unit 121 determines whether the number of data is sufficient. If the number of data is sufficient, the processing proceeds to S1002, and if insufficient, the processing returns to S302.

### (S1002)

The control unit 121 determines whether replacement of the calibration sample is necessary. If the replacement of the calibration sample is unnecessary, the processing proceeds to S308, and if the replacement of the calibration sample is necessary, the processing returns to S1001 via S1003. Whether the replacement of the calibration sample is necessary is determined based on whether a relation between the shape and position of the calibration sample and a control amount of the aberration corrector is obtained for all of prepared calibration samples. That is, if the relation is obtained for all of the prepared calibration samples, it is determined that the replacement of the calibration sample is unnecessary.

### (S1003)

The calibration sample is unloaded from the scanning electron microscope. After the calibration sample is unloaded in S1003, another calibration sample is loaded in S301.

### (S308)

As in the first embodiment, the control unit 121 creates a correction table by using the control amount of the aberration corrector 131 with which the aberration becomes less than the threshold value at each measurement position 401. The created correction table is stored in the storage unit 123.

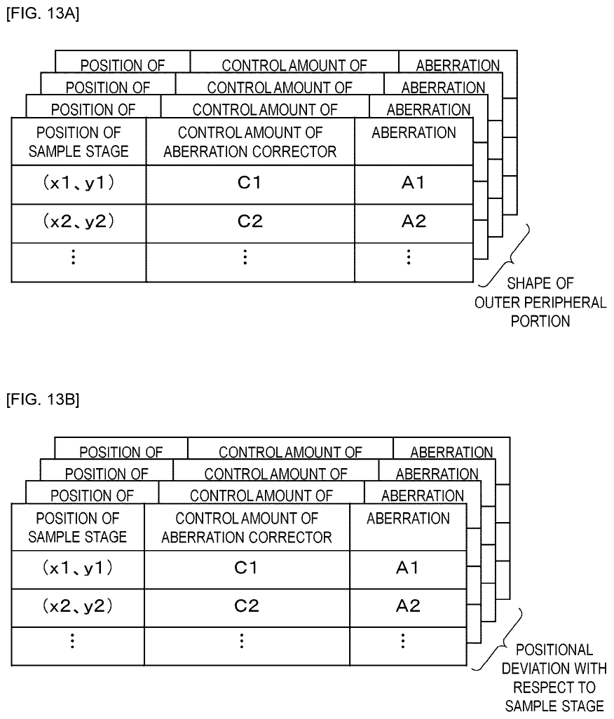

FIGS. 13A and 13B illustrate examples of the correction table created in the second embodiment. The correction table illustrated in FIG. 13A indicates a relation between the position of the sample stage 109 and the control amount of the aberration corrector 131 for each shape of the outer peripheral portion of the sample 108. The correction table illustrated in FIG. 13B indicates a relation between the position of the sample stage 109 and the control amount of the aberration corrector 131 for each positional deviation of the sample 108 with respect to the sample stage 109.

### (S309)

As in the first embodiment, the calibration sample is unloaded from the scanning electron microscope.

According to the processing flow described with reference to FIG. 10, the correction table indicating the relation between the position of the sample stage 109 and the control amount of the aberration corrector 131 is created for each shape and position of the sample 108. As in the first embodiment, the created correction table is used for aberration correction.

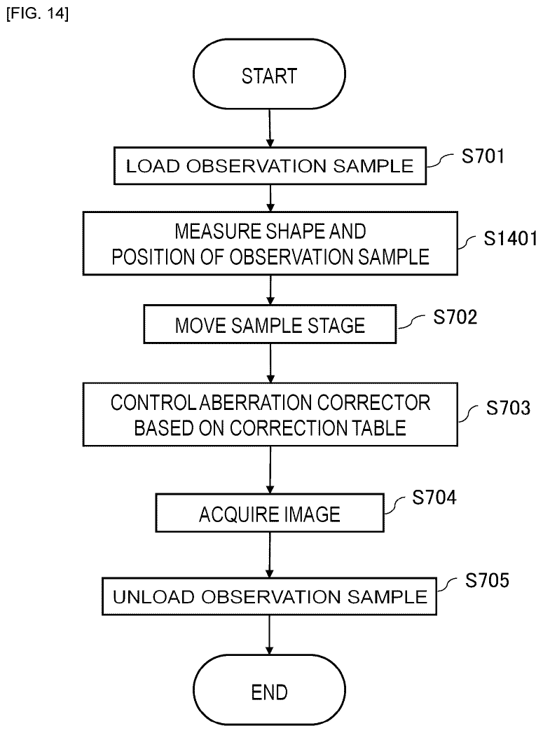

An example of a processing flow of the aberration correction according to the second embodiment will be described for each processing step with reference to FIG. 14.

### (S701)

As in the first embodiment, an observation sample is loaded into the scanning electron microscope.

### (S1401)

The control unit 121 moves the sample stage 109 holding the observation sample loaded in S701 to a position immediately below the measuring instrument 901, and causes the measuring instrument 901 to measure the shape and position of the observation sample. The measuring instrument 901 measures a cross-sectional shape of an outer edge of the observation sample and a positional deviation of the observation sample with respect to the sample stage 109, and transmits measurement values to the control unit 121.

The shape and position of the observation sample may be measured by using the height sensor illustrated in FIG. 12. The shape and position of the observation sample may be measured in advance outside the scanning electron microscope, and the values measured in advance may be read out by the control unit 121. Throughput can be improved by using the height sensor and reading out values measured in advance.

### (S702)

As in the first embodiment, the control unit 121 moves the sample stage 109 in a manner that an observation region of an outer peripheral portion of the observation sample is provided at the position irradiated with an electron beam, and acquires a position of the sample stage 109 after the movement.

### (S703)

The control unit 121 acquires the control amount of the aberration corrector 131 by collating the cross-sectional shape and positional deviation of the observation sample measured in S1401 and the position of the sample stage 109 acquired in S702 with the correction table. The control amount acquired from the correction table is set in the aberration corrector 131, and the aberration is corrected so as to be less than the threshold value. If the cross-sectional shape and positional deviation of the observation sample measured in S1401 and the position of the sample stage 109 acquired in S702 are not stored in the correction table, the control amount at the position may be calculated by interpolation processing.

### (S704)

The control unit 121 operates each of the parts in the housing 110 to acquire an observation image of the observation sample. Since the aberration corrector 131 is controlled in a manner that the aberration becomes less than the threshold value in S703, an observation image in which distortion due to the aberration is prevented can be acquired in S704.

### (S705)

The observation sample is unloaded from the scanning electron microscope.

According to the processing flow described with reference to FIG. 14, the aberration corrector 131 is operated based on the position of the sample stage 109 when the outer peripheral portion of the observation sample is observed and the cross-sectional shape and positional deviation of the observation sample, and the observation image in which distortion due to the aberration is prevented can be acquired. The observation image thus acquired can be used for dimension measurement, defect inspection, and the like of the outer peripheral portion of the observation sample.

### Third Embodiment

In the first embodiment, the correction of the aberration that occurs when the outer peripheral portion of the observation sample is observed has been described. In a third embodiment, in addition to correction of an aberration, correction of a disturbance of an electric field in an outer peripheral portion of an observation sample will be described. The same reference numerals are given to the same configurations and processing as those of the first embodiment, and the description thereof will be omitted or simplified.

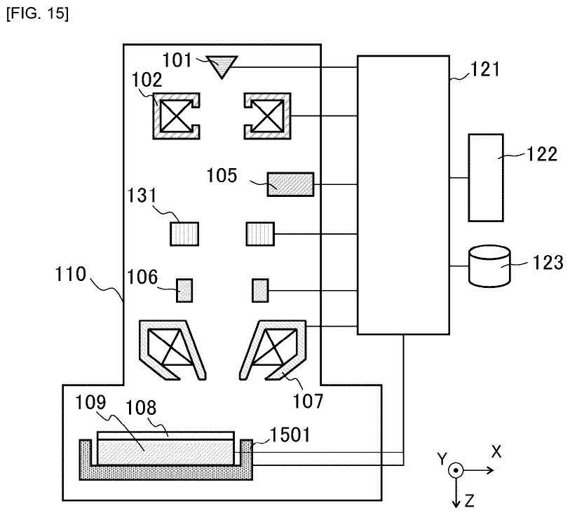

An overall configuration of a scanning electron microscope according to the third embodiment will be described with reference to FIG. 15. In the scanning electron microscope according to the third embodiment, an electric field correction electrode 1501 is added to the configuration according to the first embodiment. The electric field correction electrode 1501 generates a correction electric field for correcting the disturbance of the electric field generated in the outer peripheral portion of the sample 108, and has a circular ring shape surrounding the outer peripheral portion of the sample 108. The control unit 121 applies a predetermined voltage to the electric field correction electrode 1501 to generate the correction electric field. The electric field correction electrode 1501 moves together with the sample stage 109.

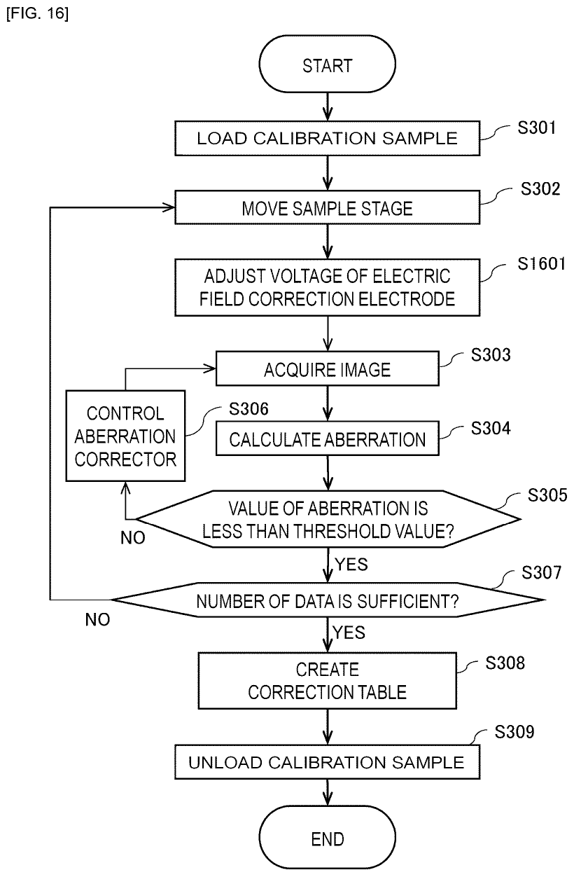

An example of a processing flow for creating a correction table according to the third embodiment will be described for each processing step with reference to FIG. 16. In the third embodiment, S1601 is added to the processing flow illustrated in FIG. 3, and thus the descriptions of the processing steps other than S1601 will be simplified.

### (S301)

As in the first embodiment, a calibration sample is loaded into the scanning electron microscope.

### (S302)

As in the first embodiment, the control unit 121 moves the sample stage 109 in a manner that an observation region of an outer peripheral portion of the calibration sample is provided at a position irradiated with an electron beam.

### (S1601)

The control unit 121 adjusts the voltage to be applied to the electric field correction electrode 1501 at the position of the sample stage 109 moved in S302. That is, the voltage is adjusted in a manner that a desired position is irradiated with the electron beam.

### (S303)

As in the first embodiment, the control unit 121 operates each of the parts in the housing 110 to acquire an observation image of the outer peripheral portion of the calibration sample.

### (S304)

As in the first embodiment, the control unit 121 calculates an aberration based on the observation image acquired in S303.

### (S305)

As in the first embodiment, the control unit 121 determines whether the value of the aberration calculated in S304 is less than a threshold value determined in advance. If the value of the aberration is less than the threshold value, the processing proceeds to S307, and if the value of the aberration is equal to or larger than the threshold value, the processing returns to S303 via S306.

### (S306)

As in the first embodiment, the control unit 121 controls the aberration corrector 131.

### (S307)

As in the first embodiment, the control unit 121 determines whether the number of data is sufficient. If the number of data is sufficient, the processing proceeds to S1202, and if insufficient, the processing returns to S302.

### (S308)

As in the first embodiment, the control unit 121 creates a correction table by using a control amount of the aberration corrector 131 with which the aberration becomes less than the threshold value at each measurement position 401. The correction table also stores the voltage to be applied to the electric field correction electrode 1501.

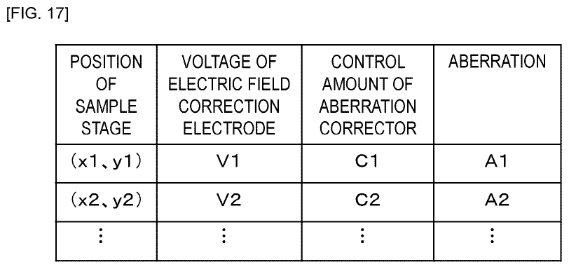

FIG. 17 illustrates an example of the correction table created in the third embodiment. In the correction table illustrated in FIG. 17, the voltage to be applied to the electric field correction electrode 1501 and the control amount of the aberration corrector 131 are associated for each position of the sample stage 109. The created correction table is stored in the storage unit 123.

### (S309)

As in the first embodiment, the calibration sample is unloaded from the scanning electron microscope.

According to the processing flow described with reference to FIG. 16, a correction table indicating a relation between the position of the sample stage 109, the voltage to be applied to the electric field correction electrode 1501, and the control amount of the aberration corrector 131 is created. As in the first embodiment, the created correction table is used for aberration correction.

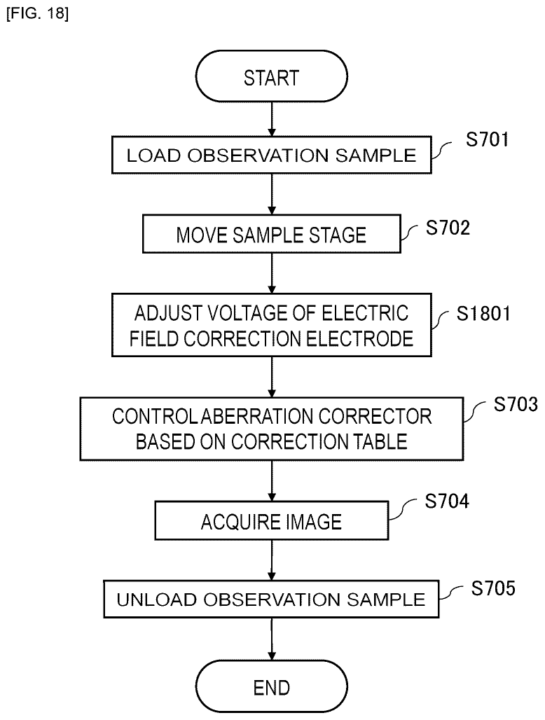

An example of a processing flow of the aberration correction according to the third embodiment will be described for each processing step with reference to FIG. 18.

### (S701)

As in the first embodiment, an observation sample is loaded into the scanning electron microscope.

### (S702)

As in the first embodiment, the control unit 121 moves the sample stage 109 in a manner that an observation region of an outer peripheral portion of the observation sample is provided at the position irradiated with an electron beam, and acquires a position of the sample stage 109 after the movement.

### (S1801)

The control unit 121 acquires the voltage to be applied to the electric field correction electrode 1501 by collating the position of the sample stage 109 acquired in S702 with the correction table. The voltage to be applied acquired from the correction table is set in the electric field correction electrode 1501, and the disturbance of the electric field generated in the outer peripheral portion of the sample 108 is corrected. When the position of the sample stage 109 acquired in S702 is not stored in the correction table, the voltage to be applied at the position may be calculated by interpolation processing.

### (S703)

The control unit 121 acquires the control amount of the aberration corrector 131 by collating the position of the sample stage 109 acquired in S702 with the correction table. The control amount acquired from the correction table is set in the aberration corrector 131, and the aberration is corrected so as to be less than the threshold value. When the position of the sample stage 109 acquired in S702 is not stored in the correction table, the control amount at the position may be calculated by interpolation processing.

### (S704)

The control unit 121 operates each of the parts in the housing 110 to acquire an observation image of the observation sample. Since the aberration corrector 131 is controlled in a manner that the aberration becomes less than the threshold value in S703, an observation image in which distortion due to the aberration is prevented can be acquired in S704.

### (S705)

The observation sample is unloaded from the scanning electron microscope.

According to the processing flow described with reference to FIG. 18, the voltage to be applied to the electric field correction electrode 1501 and the control amount of the aberration corrector 131 are controlled based on the position of the sample stage 109 when the outer peripheral portion of the observation sample is observed. As a result, a positional deviation of the electron beam emitted onto the observation sample is prevented, and an observation image with corrected aberration can be acquired. The observation image thus acquired can be used for dimension measurement, defect inspection, and the like of the outer peripheral portion of the observation sample.

A plurality of embodiments of the charged particle beam device according to the invention have been described above. The invention is not limited to the above embodiments, and can be embodied by modifying components without departing from the gist of the invention. A plurality of components disclosed in the above embodiments may be combined appropriately. For example, a correction table obtained by appropriately combining the correction tables exemplified in FIGS. 6B, 13A, 13B, and 17 may be used for aberration correction. Further, some components may be deleted from all the components shown in the above embodiment.

### REFERENCE SIGNS LIST

101: electron gun
102: condenser lens
105: detector
106: deflector
107: objective lens
108: sample
109: sample stage
110: housing
121: control unit
122: input and output unit
123: storage unit
131: aberration corrector
201A: electrode
201B: electrode
202A: magnetic pole
202B: magnetic pole
211A: magnetic pole
211B: magnetic pole
212A: magnetic pole
212B: magnetic pole
213A: magnetic pole
213B: magnetic pole
400: center point
401: measurement position
901: measuring instrument
1101: bevel
1102: apex
1201: light emitting unit
1202: light receiving unit
1501: electric field correction electrode

1. A charged particle beam device, comprising:
a sample stage configured to hold a sample;
a charged particle beam source configured to emit a charged particle beam to be emitted onto the sample;
a lens configured to focus the charged particle beam on the sample;
an aberration corrector configured to correct an aberration of the charged particle beam;
a deflector configured to perform scanning with the charged particle beam;
a detector configured to detect a charged particle emitted from the sample by being scanned with the charged particle beam; and
a control unit configured to generate an observation image of the sample based on a detection signal output from the detector and control an operation of each of the parts, wherein
the control unit controls the aberration corrector by collating a position of the sample stage when an outer peripheral portion of the sample is observed with a correction table indicating a relation between the position of the sample stage and a control amount of the aberration corrector.

2. The charged particle beam device according to claim 1, wherein
the correction table is created for each irradiation condition of the charged particle beam, and
the control unit performs control according to the irradiation condition of the charged particle beam together with the position of the sample stage when the outer peripheral portion of the sample is observed.

3. The charged particle beam device according to claim 1, further comprising:
a measurement unit configured to measure a cross-sectional shape of the outer peripheral portion of the sample, wherein
the correction table is created for each cross-sectional shape of the sample, and
the control unit performs control according to the cross-sectional shape of the sample together with the position of the sample stage when the outer peripheral portion of the sample is observed.

4. The charged particle beam device according to claim 1, further comprising
a measurement unit configured to measure a positional deviation of the sample with respect to the sample stage, wherein
the correction table is created for each positional deviation of the sample with respect to the sample stage, and
the control unit performs control according to the positional deviation of the sample with respect to the sample stage together with the position of the sample stage when the outer peripheral portion of the sample is observed.

5. The charged particle beam device according to claim 1, further comprising:
an electric field correction electrode configured to generate a correction electric field for correcting a disturbance of an electric field generated in the outer peripheral portion of the sample, wherein
the correction table further indicates a relation between the position of the sample stage and a voltage to be applied to the electric field correction electrode, and
the control unit further controls the voltage to be applied to the electric field correction electrode according to the position of the sample stage when the outer peripheral portion of the sample is observed.

6. The charged particle beam device according to claim 1, further comprising
a display screen configured to display the observation image, wherein
the display screen includes a button for switching ON and OFF of the control for the aberration corrector.

7. The charged particle beam device according to claim 1, wherein
the aberration corrector includes a chromatic aberration corrector configured to correct a chromatic aberration.

8. The charged particle beam device according to claim 1, wherein
the aberration corrector includes a coma aberration corrector configured to correct a coma aberration.
